(19) United States
(12) Patent Application Publication
(10) Pub. No.: US 2023/0415665 A1
(43) Pub. Date: Dec. 28, 2023

(54) DISPLAY DEVICE

(71) Applicant: Shanghai Tianma Micro-Electronics Co., Ltd., Shanghai (CN)

(72) Inventors: Hitoshi YOSHIDA, Kawasaki (JP); Futoshi Nakanishi, Kawasaki (JP); Noriyuki Itou, Kawasaki (JP); Akira Banjouya, Kawasaki (JP); Akira Suzuki, Kawasaki (JP); Shingo Asaka, Kawasaki (JP); Koetsu Ishikawa, Kawasaki (JP)

(73) Assignee: Shanghai Tianma Micro-Electronics Co., Ltd., Shanghai (CN)

(21) Appl. No.: 18/336,135

(22) Filed: Jun. 16, 2023

(30) Foreign Application Priority Data
Jun. 23, 2022 (JP) 2022-100829
Feb. 13, 2023 (JP) 2023-019683

(51) Int. Cl. B60R 11/02

(52) U.S. Cl. CPC B60R 11/0235

(57) ABSTRACT

A display device includes a display having a display surface, and a holder that is provided on a surface of a side opposite the display surface of the display and that fixes the display to the fixing target. In a state in which the display device is fixed to the fixing target, when an impactor impacts the display surface on a center line that passes through a center of a display region of the display and that is perpendicular to the display region, a rigidity to impact of the display device is asymmetrical.

### CROSS-REFERENCE TO RELATED APPLICATIONS

This application claims the benefit of Japanese Patent Application No. 2022-100829, filed on Jun. 23, 2022, and Japanese Patent Application No. 2023-019683, filed on Feb. 13, 2023, of which the entirety of the disclosures is incorporated by reference herein.

### FIELD OF THE INVENTION

The present disclosure relates generally to a display device.

### BACKGROUND OF THE INVENTION

In order to enhance the safety of riders (crew, passengers, and the like) on vehicles, trains, and the like, it is necessary to reduce injury done to the riders by display devices provided in the vehicles, trains, and the like. For example, the European standards for vehicles (ECE-R21: the Economic Commission for Europe of the United Nations (UN/ECE)-Regulation No. 21) includes a standard for the deceleration of a headform when a headform resembling the head of a rider impacts a display device. ECE-R21 indicates that, for example, the deceleration of the headform when the headform impacts the display device shall not exceed 80 G continuously for more than 3 ms.

Additionally, instrument panel structures are known that, when a vehicle collides, can mitigate the impact that a crew member is subjected to from a display provided in the cabin of the vehicle. For example, Unexamined Japanese Patent Application Publication No. 2013-144523 discloses an instrument panel structure including an instrument panel reinforcement provided on a back side of an instrument panel, a cylindrical fixed member fixed to the instrument panel reinforcement, a bearing member mounted on the fixed member, and a support member supported by the fixed member via the bearing member. A display, which is provided on the instrument panel, is fixed to a rear end in a vehicle front-back direction of the support member. The support member is supported by the fixed member so as to be slidable along an axial direction of the fixed member when an impact load is inputted to the display. In the instrument panel structure of Unexamined Japanese Patent Application Publication No. 2013-144523, the support member to which the display is fixed slides along the axial direction of the fixed member to mitigate the impact that the crew member is subjected to from the display.

In the instrument panel structure of Unexamined Japanese Patent Application Publication No. 2013-144523, the fixed member, the bearing member, and the support member are required to provide the display in the cabin and, furthermore, the configuration is complex.

### SUMMARY OF THE INVENTION

A display device of the present disclosure includes:
a display including a display surface; and
a holder that is provided on a surface of a side opposite the display surface of the display, and that fixes the display to a fixing target, wherein
in a state in which the display device is fixed to the fixing target, when an impactor impacts the display surface on a center line that passes through a center of a display region of the display and that is perpendicular to the display region, a rigidity to impact of the display device is asymmetrical.

It is to be understood that both the foregoing general description and the following detailed description are exemplary and explanatory and are not restrictive of this disclosure.

### BRIEF DESCRIPTION OF THE DRAWINGS

A more complete understanding of this application can be obtained when the following detailed description is considered in conjunction with the following drawings, in which:

FIG. 1 is a plan view illustrating a display device according to Embodiment 1;

FIG. 2 is a cross-sectional view of the display device illustrated in FIG. 1, taken along line A-A;

FIG. 3 is a cross-sectional view illustrating a display according to Embodiment 1;

FIG. 4 is a plan view illustrating a liquid crystal display panel according to Embodiment 1;

FIG. 5 is a plan view illustrating a holder according to Embodiment 1;

FIG. 6 is a cross-sectional view of the holder illustrated in FIG. 5, taken along line B-B;

FIG. 7 is a cross-sectional view illustrating an impactor and an opening of the holder according to Embodiment 1;

FIG. 8 is a drawing illustrating a deceleration of the impactor according to Embodiment 1;

FIG. 9 is a schematic drawing for explaining a change in the deceleration of the impactor, according to Embodiment 1;

FIG. 10 is a schematic drawing for explaining a change in the deceleration of the impactor, according to Embodiment 1;

FIG. 11 is a drawing illustrating the dimensions of the various components of the display device according to Embodiment 1;

FIG. 12 is a drawing illustrating the dimensions of the various components of the display device according to Embodiment 1;

FIG. 13 is a drawing illustrating the deceleration of the impactor according to a comparative example;

FIG. 14 is a drawing illustrating the deceleration of the impactor according to Embodiment 1;

FIG. 15 is a drawing illustrating the deceleration of the impactor according to Embodiment 1;

FIG. 16 is a perspective view illustrating a holder according to Embodiment 2;

FIG. 17 is a cross-sectional view illustrating a display device according to Embodiment 2;

FIG. 18 is a cross-sectional view illustrating a display device according to Embodiment 3;

FIG. 19 is a plan view illustrating a holder according to Embodiment 4;

FIG. 20 is a cross-sectional view of the holder illustrated in FIG. 19, taken along line C-C;

FIG. 21 is a cross-sectional view illustrating an impactor and an opening of the holder according to Embodiment 4;

FIG. 22 is a schematic drawing for explaining a change in the deceleration of the impactor, according to Embodiment 4;

FIG. 23 is a schematic drawing for explaining a change in the deceleration of the impactor, according to Embodiment 4;

FIG. 24 is a plan view illustrating a display device according to Embodiment 5;

FIG. 25 is a cross-sectional view of the display device illustrated in FIG. 24, taken along line D-D;

FIG. 26 is a plan view illustrating a display device according to Embodiment 6;

FIG. 27 is a cross-sectional view of the display device illustrated in FIG. 26, taken along line E-E;

FIG. 28 is a plan view illustrating a display device according to Embodiment 7;

FIG. 29 is a cross-sectional view of the display device illustrated in FIG. 28, taken along line F-F;

FIG. 30 is a plan view illustrating a display device according to Embodiment 8;

FIG. 31 is a cross-sectional view of the display device illustrated in FIG. 30, taken along line G-G;

FIG. 32 is a plan view illustrating a housing and an adhesive member according to Embodiment 8;

FIG. 33 is a cross-sectional view of the housing and the adhesive member illustrated in FIG. 32, taken along line J-J;

FIG. 34 is a schematic drawing for explaining a change in the deceleration of the impactor, according to Embodiment 8;

FIG. 35 is a schematic drawing for explaining a change in the deceleration of the impactor, according to Embodiment 8;

FIG. 36 is a drawing illustrating the deceleration of an impactor according to Embodiment 9;

FIG. 37 is a drawing illustrating the deceleration of the impactor according to Embodiment 9;

FIG. 38 is a drawing illustrating the deceleration of the impactor according to Embodiment 9;

FIG. 39 is a cross-sectional view illustrating a display device according to Embodiment 10;

FIG. 40 is a drawing illustrating the dimensions of the various components of the display device according to Embodiment 10;

FIG. 41 is a drawing illustrating the dimensions of the various components of the display device according to Embodiment 10;

FIG. 42 is a schematic drawing for explaining a change in the deceleration of the impactor, according to Embodiment 10;

FIG. 43 is a schematic drawing for explaining a change in the deceleration of the impactor, according to Embodiment 10; and

FIG. 44 is a cross-sectional view illustrating a display device according to a modified example.

### DETAILED DESCRIPTION

Hereinafter, a display device according to various embodiments is described while referencing the drawings.

### Embodiment 1

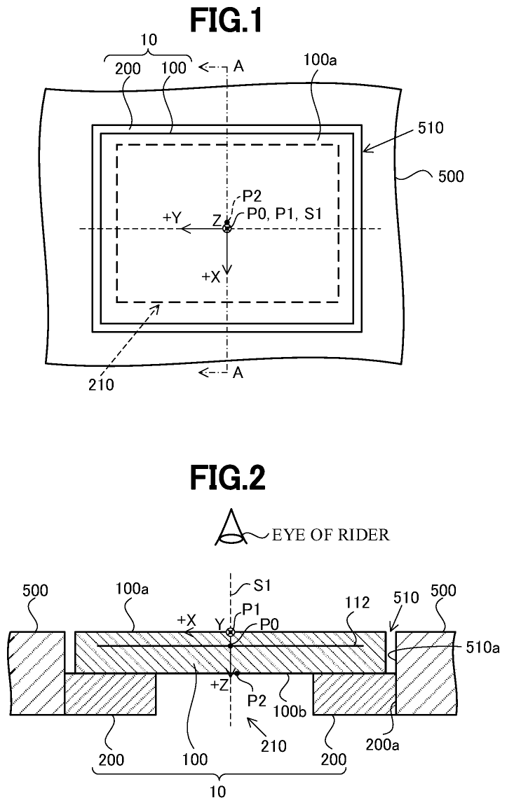

A display device 10 according to the present embodiment is described while referencing FIGS. 1 to 15. The display device 10 is mounted in a vehicle, an airplane, on a household appliance, a piece of furniture, or the like. In the present embodiment and the following embodiments, examples in which the display device 10 is mounted in a vehicle are described.

As illustrated in FIGS. 1 and 2, the display device 10 is fitted in an open section 510 of an instrument panel 500 of a vehicle, and is fixed to the open section 510. In one example, the instrument panel 500 is formed from resin and the open section 510 has a rectangular shape. The instrument panel 500 corresponds to the fixing target.

In the present embodiment, as described later, when an impactor Q impacts a display surface 100a on a center line S1 that passes through a center P0 of a display region 112 of a display 100 and that is perpendicular to the display region 112, the rigidity to impact of the display device 10 fixed to the instrument panel 500 is asymmetrical. In one example, the impactor Q is headform that resembles the head of a rider. In the present embodiment and the following embodiments, the display device 10 is described for an example in which an impactor (headform) Q has a spherical shape with a diameter (that is, a maximum width in one direction) QD. Additionally, the rider corresponds to a user.

The display device 10 includes the display 100 and a holder 200. The display 100 displays characters, images, and the like. The holder 200 fixes the display device 10 in the open section 510 of the instrument panel 500. Note that, to facilitate comprehension, in the present specification, the surface on the rider side of the display 100 is defined as the display surface 100a of the display 100. Additionally, with an impact position P1 where the impactor Q impacts the display surface 100a as the origin, in the display device 10 of FIG. 1, the lateral direction (the downward direction on paper) is referred to as the “+X direction”, the longitudinal direction (the left direction on paper) is referred to as the “+Y direction”, and the direction perpendicular to the +X direction and the +Y direction (the depth direction on paper, the side opposite the rider) is referred to as the “+Z direction.”

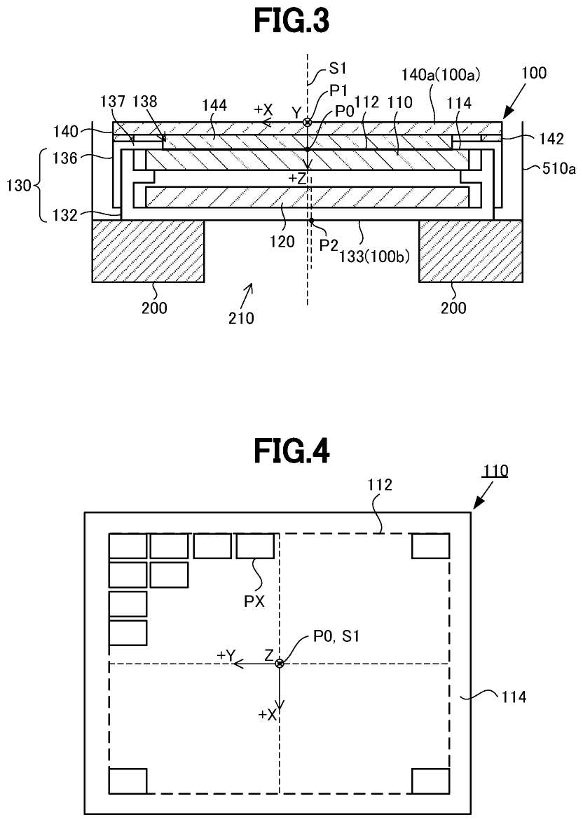

As illustrated in FIGS. 1 and 2, the display 100 of the display device 10 is fixed to an inner wall 510a of the open section 510 via the holder 200. As illustrated in FIG. 3, the display 100 includes a liquid crystal display panel 110, a back light 120, a housing 130, and a cover 140. Note that, to facilitate comprehension, the hatching of the housing 130 is omitted from FIG. 3.

In one example, the liquid crystal display panel 110 of the display 100 is implemented as a transmissive liquid crystal display panel that is active matrix driven by thin film transistors (TFT). The liquid crystal display panel 110 displays the characters, images, and the like by modulating light from the back light 120. As illustrated in FIG. 4, the liquid crystal display panel 110 includes the display region 112 and a periphery 114. The display region 112 is a region in which pixels PX are arranged in a matrix and is capable of displaying the characters, images, and the like. The periphery 114 is a region in which wiring, driving circuits, and the like are disposed. As illustrated in FIGS. 3 and 4, in the present specification, a line that passes through the center P0 of the display region 112 and that is perpendicular to the display region 112 is defined as a center line S1.

As illustrated in FIG. 3, the back light 120 of the display 100 is disposed on a back surface side (the +Z side) of the liquid crystal display panel 110. The back light 120 is the light source of the liquid crystal display panel 110, and emits white light on the liquid crystal display panel 110. The back light 120 includes a white light emitting diode (LED), a reflective sheet, a diffusion sheet, a lighting circuit, and the like (all not illustrated in the drawings).

The housing 130 of the display 100 accommodates the liquid crystal display panel 110 and the back light 120. The housing 130 includes a chassis 132 and a bezel 136.

The chassis 132 has a box-like shape, and is formed from a resin or a metal. The chassis 132 accommodates, on an inner side thereof, the liquid crystal display panel 110 and the back light 120. The liquid crystal display panel 110 and the back light 120 are disposed on the bottom of the chassis 132. The holder 200 is provided on a bottom surface 133 of the chassis 132. In the present embodiment, the bottom surface 133 of the chassis 132 corresponds to a surface 100b on the side opposite the display surface 100a of the display 100.

The bezel 136 has a box-like shape. An open section 138 is provided on a bottom 137 of the bezel 136. In one example, the bezel 136 is formed from a metal. The bezel 136 covers the chassis 132 with the bottom 137 facing the −Z side. The bezel 136 protects the periphery 114 of the liquid crystal display panel 110. The display region 112 of the liquid crystal display panel 110 is exposed through the open section 138.

In one example, the cover 140 of the display 100 is formed in a rectangular shape from a light-transmitting resin. The cover 140 is provided on the housing 130 (the bottom 137 of the bezel 136) via an adhesive member 142. The cover 140 protects the liquid crystal display panel 110. The adhesive member 142 is implemented as an adhesive, double-sided tape, or the like. The adhesive member 142 is provided on the bottom 137 (portion corresponding to a top surface of a side plate of the housing 130) of the bezel 136. Space between the cover 140 and the liquid crystal display panel 110 is filled with a light-transmitting adhesive 144 (for example, optical clear adhesive (OCA)). In the present embodiment, a surface 140a on the −Z side (the rider side) of the cover 140 corresponds to the display surface 100a of the display 100. Additionally, the impactor Q impacts the display surface 100a (the surface 140a of the cover 140) of the display 100 on the center line S1 and, as such, the intersection of the center line S1 and the display surface 100a (the surface 140a) corresponds to the impact position P1 where the impactor Q impacts the display surface 100a.

The holder 200 of the display device 10 fixes the display device 10 (the display 100) in the open section 510 of the instrument panel 500 via a non-illustrated adhesive. The holder 200 is provided, via an adhesive, on the surface 100b (the bottom surface 133 of the chassis 132) on the side opposite the display surface 100a of the display 100. Additionally, an outer circumferential surface 200a of the holder 200 is adhered to the inner wall 510a of the open section 510 of the instrument panel 500 via an adhesive.

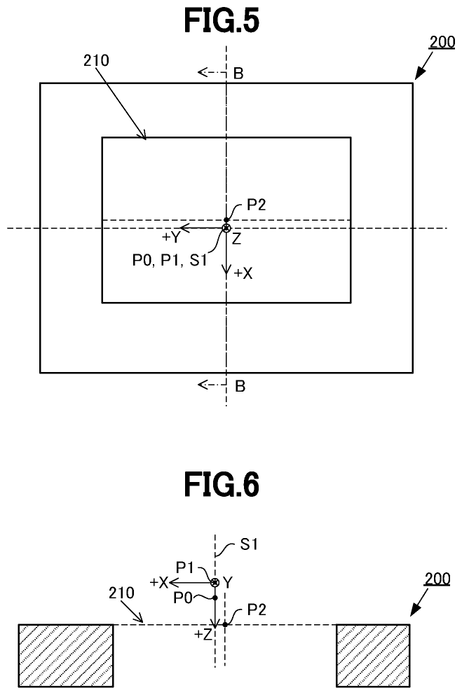

The holder 200 is formed from a metal (for example, stainless steel) or a resin. As illustrated in FIGS. 5 and 6, an external shape of the holder 200 is a frame shape that conforms to the inner shape of the open section 510 of the instrument panel 500. Additionally, a rectangular open section 210 is provided in a center section of the holder 200.

In the present embodiment, when viewing the display device 10 from above, the position of a center P2 of the opening on the display 100 side (the −Z side) of the open section 210 is offset in the −X direction from the position of the center P0 of the display region 112. The position of the center P2 of the opening on the display 100 side of the open section 210 is offset from the position of the center P0 of the display region 112, and the holder 200 fixes the display 100 in the open section 510 of the instrument panel 500. As such, when the impactor Q impacts the display surface 100a on the center line S1 that passes through the center P0 of the display region 112 and that is perpendicular to the display region 112, the rigidity to impact of the holder 200 (that is, the display device 10) fixed to the instrument panel 500 is asymmetrical (asymmetrical in the X direction). More specifically, in the holder 200 (the display device 10), the rigidity of the +X side with respect to the center line S1 is higher than the rigidity of the −X side with respect to the center line S1.

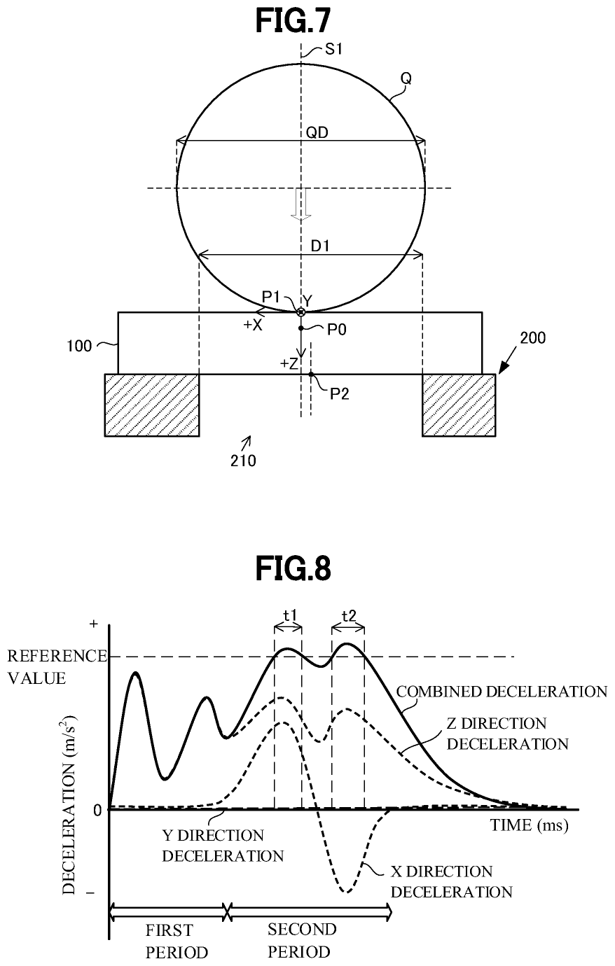

As illustrated in FIG. 7, a width D1 in one direction (the X direction) of the opening on the display 100 side of the open section 210 is less than the maximum width QD in the one direction (the X direction) of the impactor Q. Due to this, the impactor Q can be prevented from penetrating the display device 10. Note that the hatching of the impactor Q and the display 100 are omitted from FIG. 7. The hatching of the display 100, the impactor Q, and the like may be omitted from the following drawings as well.

Next, a deceleration of the impactor Q in a case in which the impactor Q impacts the display surface 100a on the center line S1 that passes through the center P0 of the display region 112 and that is perpendicular to the display region 112 is described while referencing FIGS. 7 to 15. Here, the deceleration of the impactor Q is described for an example of a case in which the spherical impactor Q moves on the center line S1 from the −Z side and impacts the display surface 100a on the center line S1, as illustrated in FIG. 6.

FIG. 8 illustrates the deceleration of the impactor Q. In FIG. 8, X direction deceleration, Y direction deceleration, and Z direction deceleration each express deceleration in each direction. In the X direction deceleration, the Y direction deceleration, and the Z direction deceleration, the value of the deceleration being positive indicates + direction deceleration (for example, +X direction deceleration), and the value of the deceleration being negative indicates − direction deceleration (for example, −X direction deceleration). Combined deceleration expresses deceleration obtained by combining the X direction deceleration, the Y direction deceleration, and the Z direction deceleration.

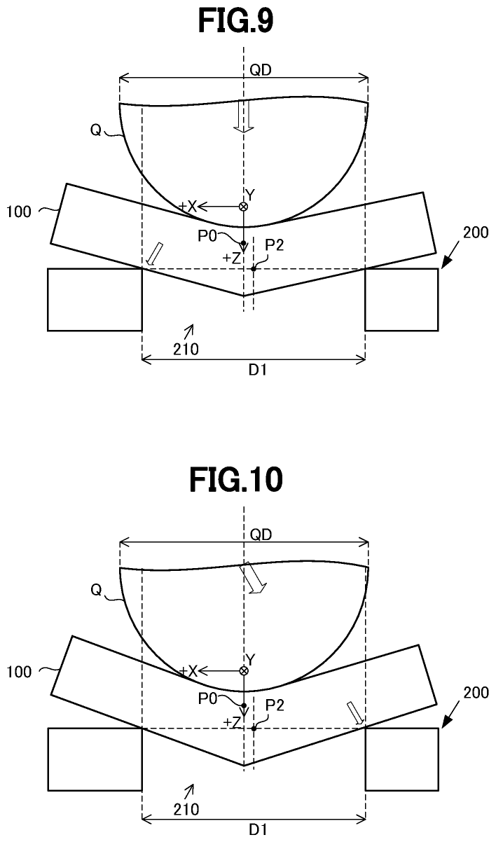

As illustrated in FIG. 8, when the impactor Q impacts the display surface 100a (the impact position P1) on the center line S1, in a first period, +Z direction deceleration occurs due to the bending of the display 100, and two peaks corresponding to the configuration of the display 100 occur in the +Z direction deceleration and the combined deceleration. In a second period after the first period, the rigidity on the +X side of the holder 200 is higher than the rigidity on the −X side and, as such, firstly, the load caused by the impactor Q is mainly applied to the +X side of the holder 200, as illustrated in FIG. 9. As a result, both +Z direction deceleration and +X direction deceleration occur, as illustrated in FIG. 8. Next, since the rigidity on the +X side of the holder 200 is higher than the rigidity on the −X side, the impactor Q moves to the −X side and the load caused by the impactor Q is mainly applied to the −X side of the holder 200, as illustrated in FIG. 10. As a result, both +Z direction deceleration and −X direction deceleration occur, as illustrated in FIG. 8. Specifically, the direction in which the load is mainly applied changes with the passage of time, and the X direction deceleration fluctuates from the +X direction to the −X direction. As a result, two peaks occur in the combined deceleration and, as such, the periods t1 and t2 in which the combined deceleration continuously exceeds the reference value, that is, the amount of time in which the deceleration of the impactor Q is great, can be shortened.

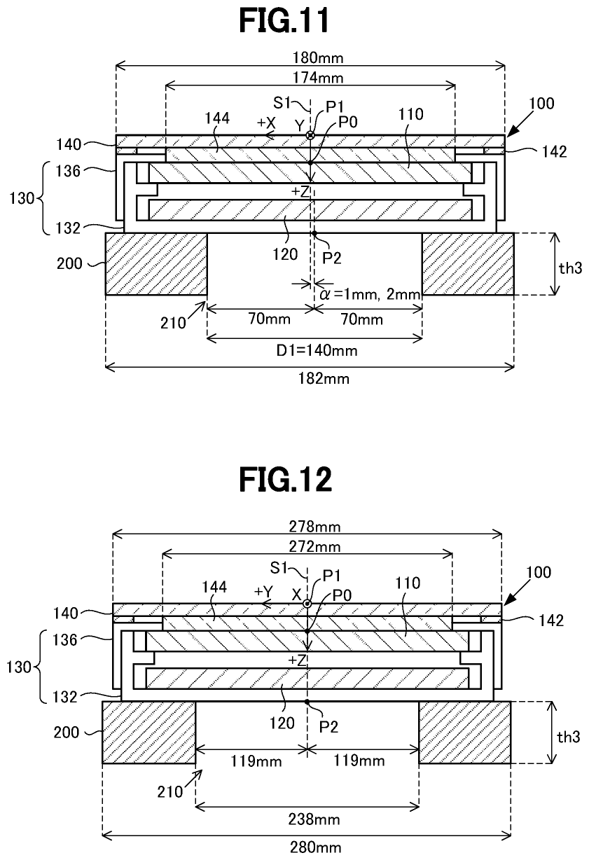

Next, the deceleration of the impactor Q is described using a more specific example. In one example, the dimensions of the various components of the display device 10 of the present embodiment are as illustrated in FIGS. 11 and 12 (external form of the cover 140 and external form of the bezel 136 of the housing 130: 180 mm×278 mm, the open section 138 of the bezel 136: 174 mm×272 mm, external form of the holder 200: 182 mm×280 mm, the open section of the holder 200: 140 mm×238 mm, and the offset α of the position of the center P0 of the display region 112 from the position of the center P2 of the opening: 1 mm, 2 mm). This display device 10 was fixed in the open section 510 of the instrument panel 500. Then, an impact tester was used to cause a spherical impactor Q having a diameter (maximum width) QD of 165 mm and a weight of 6.8 kg to move at 24.1 km/h on the center line S1 from the −Z side and impact the display surface 100a (the impact position P1) on the center line S1.

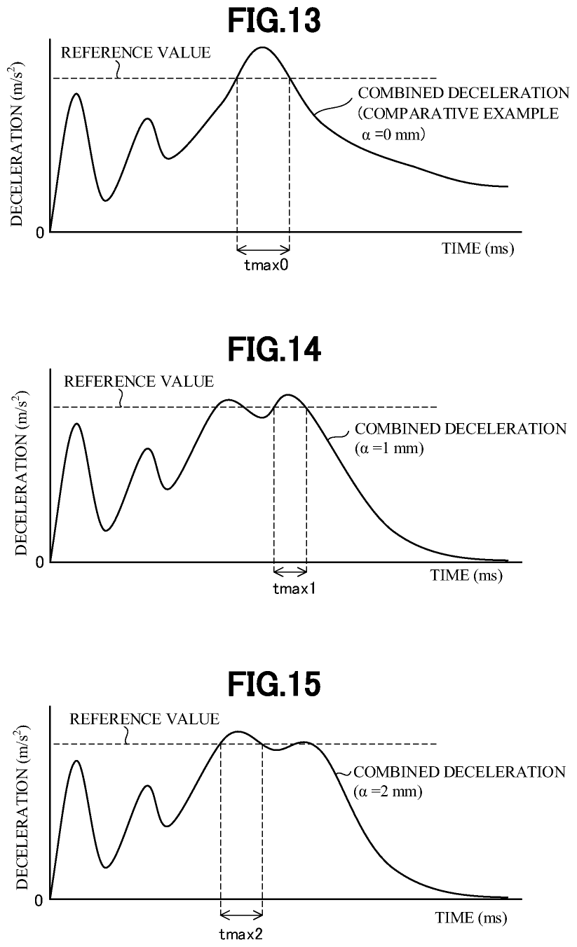

An amount of time tmax0 in which the combined deceleration continuously exceeds the reference value in a case in which there is no offset of the position of the center P0 of the display region 112 from the position of the center P2 of the opening of the open section 210 (FIG. 13, Comparative Example: α=0 mm) is set as 100%. A longest amount of time tmax1 of the amounts of time in which the combined deceleration continuously exceeds the reference value in a case in which the offset α of the position of the center P0 of the display region 112 from the position of the center P2 of the opening is 1 mm (FIG. 14) was 87% of tmax0. A longest amount of time tmax2 of the amounts of time in which the combined deceleration continuously exceeds the reference value in a case in which the offset α of the position of the center P0 of the display region 112 from the position of the center P2 of the opening is 2 mm (FIG. 15) was 91% of tmax0. Thus, the display device 10 of the present embodiment can shorten the amount of time in which the deceleration of the impactor Q is great.

As described above, when viewing the display device 10 from above, the position of the center P2 of the opening on the display 100 side of the open section 210 of the holder 200 is offset from the position of the center P0 of the display region 112 and, as such, when the impactor Q impacts the display surface 100a on the center line S1 that passes through the center P0 of the display region 112 and that is perpendicular to the display region 112, the rigidity to impact of the display device 10 (the holder 200) fixed to the instrument panel 500 is asymmetrical. Due to this, the display device 10 can shorten the amount of time in which the deceleration of the impactor Q is great. Accordingly, the display device 10 can enhance rider safety.

### Embodiment 2

In Embodiment 1, the holder 200 includes the open section 210. A configuration is possible in which the holder 200 includes a recess 220 instead of the open section 210. As with the display device 10 of Embodiment 1, the display device 10 of the present embodiment includes the display 100 and the holder 200. The display device 10 of the present embodiment is fixed in the open section 510 of the instrument panel 500. The configuration of the display 100 of the present embodiment is the same as that of the display 100 of Embodiment 1 and, as such, the holder 200 of the present embodiment is described.

As with the holder 200 of Embodiment 1, the holder 200 of the present embodiment is provided on the surface 100b (the bottom surface 133 of the chassis 132) of the display 100 by an adhesive. Additionally, the outer circumferential surface 200a of the holder 200 of the present embodiment is adhered to the inner wall 510a of the open section 510 of the instrument panel 500 by an adhesive.

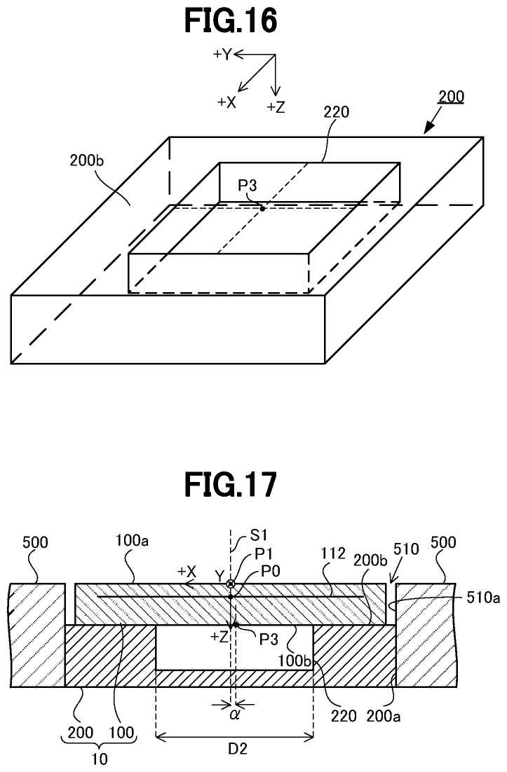

As illustrated in FIGS. 16 and 17, the holder 200 of the present embodiment has a rectangular shape that conforms to the inner shape of the open section 510 of the instrument panel 500. The holder 200 of the present embodiment includes the recess 220 on the surface 200b that opposes the display 100. The recess 220 has a rectangular shape.

As with the position of the center P2 of the opening of the open section 210 of Embodiment 1, when viewing the display device 10 from above, a position of a center P3 of an opening of the recess 220 of the present embodiment is offset in the −X direction from the position of the center P0 of the display region 112. Accordingly, in the present embodiment, as in Embodiment 1, when the impactor Q impacts the display surface 100a on the center line S1 that passes through the center P0 of display region 112 and that is perpendicular to the display region 112, the rigidity to impact of the holder 200 (the display device 10) fixed to the instrument panel 500 is asymmetrical.

A width D2 in one direction (the X direction) of the opening of the recess 220 is less than the maximum width QD in the one direction (the X direction) of the impactor Q. Due to this, as in Embodiment 1, the impactor Q can be prevented from penetrating the display device 10.

As in Embodiment 1, when the impactor Q impacts the display surface 100a on the center line S1 that passes through the center P0 of the display region 112 and that is perpendicular to the display region 112, the rigidity to impact of the display device 10 (the holder 200) fixed to the instrument panel 500 is asymmetrical and, as such, the display device 10 of the present embodiment can shorten the amount of time in which the deceleration of the impactor Q is great. Accordingly, the display device 10 of the present embodiment also can enhance rider safety.

### Embodiment 3

In Embodiment 2, the holder 200 includes the recess 220 that has a rectangular shape. Additionally, the width D2 in the one direction (the X direction) of the opening of the recess 220 is less than the maximum width QD in the one direction (the X direction) of the impactor Q. However, the shape of the recess 220 is not limited to a rectangular shape, and a configuration is possible in which a minimum width D3min in one direction of the recess 220 is less than the maximum width QD in the one direction of the impactor Q.

As with the display device 10 in Embodiment 1 and Embodiment 2, the display device 10 of the present embodiment includes the display 100 and the holder 200, and is fixed in the open section 510 of the instrument panel 500. The configuration of the display 100 of the present embodiment is the same as that of the display 100 of Embodiment 1 and, as such, the holder 200 of the present embodiment is described.

As with the holder 200 of Embodiment 2, the holder 200 of the present embodiment is provided on the surface 100b (the bottom surface 133 of the chassis 132) of the display 100 by an adhesive. Additionally, the outer circumferential surface 200a of the holder 200 of the present embodiment is adhered to the inner wall 510a of the open section 510 of the instrument panel 500 by an adhesive.

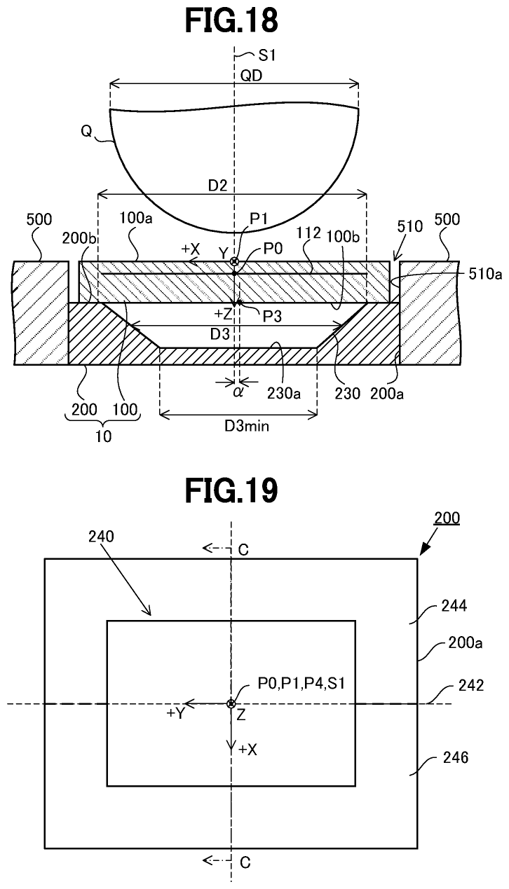

The holder 200 of the present embodiment has a rectangular shape that conforms to the inner shape of the open section 510 of the instrument panel 500. As illustrated in FIG. 18, the holder 200 of the present embodiment includes a recess 230 on the surface 200b opposing the display 100.

In the present embodiment as well, when viewing the display device 10 from above, as with the position of the center P3 of the opening of the recess 220 of Embodiment 2, the position of the center P3 of the opening of the recess 230 is offset in the −X direction from the position of the center P0 of the display region 112, Accordingly, in the present embodiment, as in Embodiment 1, when the impactor Q impacts the display surface 100a on the center line S1 that passes through the center P0 of display region 112 and that is perpendicular to the display region 112, the rigidity to impact of the holder 200 (the display device 10) fixed to the instrument panel 500 is asymmetrical.

When viewing a cross-section (XZ cross-section) including the one direction (the X direction), the recess 230 has a trapezoid shape, and a width D3 in the one direction (the X direction) of the recess 230 narrows toward the direction opposite the display 100 (the +Z direction). In the present embodiment, the width D2 in the one direction (the X direction) of the opening of the recess 230 is greater than the maximum width QD in the one direction (the X direction) of the impactor Q. Furthermore, the minimum width (width of a bottom surface 230a of the recess 230) D3min in the one direction (the X direction) of the recess 230 is less than the maximum width QD in the one direction (the X direction) of the impactor Q. Note that, in the present embodiment as well, the width D2 of the opening of the recess 230 corresponds to a maximum width in the one direction (the X direction) of the recess 230.

In the present embodiment, the minimum width D3min in the one direction (the X direction) of the recess 230 is less than the maximum width QD in the one direction (the X direction) of the impactor Q and, as such, the impactor Q can be prevented from penetrating the display device 10.

As in Embodiment 1 and Embodiment 2, when the impactor Q impacts the display surface 100a on the center line S1 that passes through the center P0 of the display region 112 and that is perpendicular to the display region 112, the rigidity to impact of the display device 10 (the holder 200) fixed to the instrument panel 500 is asymmetrical and, as such, the display device 10 of the present embodiment can shorten the amount of time in which the deceleration of the impactor Q is great. Additionally, by adjusting the width D3 of the recess 230, the display device 10 of the present embodiment can, even for smaller impacts of the impactor Q, shorten the amount of time in which the deceleration of the impactor Q is great and prevent the impactor Q from penetrating the display device 10. Accordingly, the display device 10 of the present embodiment also can enhance rider safety.

### Embodiment 4

In Embodiments 1 to 3, when viewing the display device 10 from above, the positions of the centers P2 and P3 of the opening of the holder 200 are offset from the position of the center P0 of the display region 112. A configuration is possible in which, when viewing the display device 10 from above, the position of the center of the opening of the holder 200 is not offset from the position of the center P0 of the display region 112.

As with the display device 10 in Embodiment 1 to Embodiment 3, the display device 10 of the present embodiment includes the display 100 and the holder 200, and is fixed in the open section 510 of the instrument panel 500. The configuration of the display 100 of the present embodiment is the same as that of the display 100 of Embodiment 1 and, as such, the holder 200 of the present embodiment is described.

As with the holder 200 of Embodiment 1, the holder 200 of the present embodiment is provided on the surface 100b (the bottom surface 133 of the chassis 132) of the display 100. The outer circumferential surface 200a of the holder 200 of the present embodiment is adhered to the inner wall 510a of the open section 510 of the instrument panel 500 by an adhesive.

The holder 200 of the present embodiment has a rectangular shape that conforms to the inner shape of the open section 510 of the instrument panel 500. As illustrated in FIG. 19, a rectangular open section 240 is provided in a center section of the holder 200 of the present embodiment. In the present embodiment, when viewing the display device 10 from above, a position of a center P4 of the opening on the display 100 side of the open section 240 matches the position of the center P0 of the display region 112.

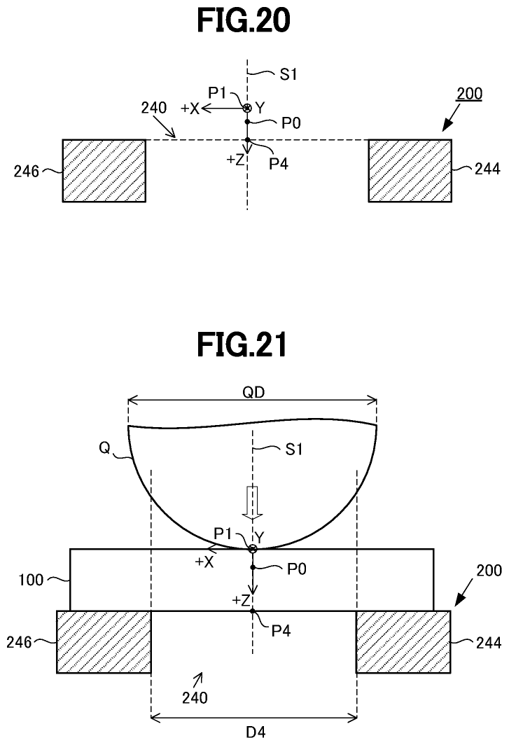

The holder 200 of the present embodiment includes a first portion 244 positioned on the −X side and a second portion 246 positioned on the +X side with respect to a center line 242 that passes through the center P4 of the open section 240 and extends in the Y direction. As illustrated in FIG. 20, the first portion 244 and the second portion 246 oppose each other in the X direction with the open section 240 therebetween. The first portion 244 and the second portion 246 are joined by welding or adhesion.

In the present embodiment, the holder 200 is formed from two types of materials that have mutually different rigidities (Young's modulus or hardness). Specifically, the first portion 244 is formed from a material that has a predetermined rigidity, and the second portion 246 is formed from a material that has a higher rigidity than the material forming the first portion 244. For example, the first portion 244 is formed from silicon rubber (Young's modulus: 4 MPa, hardness: Asker C35), urethane rubber (Young's modulus: 40 MPa, hardness: Shore A70), or the like, and the second portion 246 is formed from stainless steel (Young's modulus: 193 GPa, hardness: Shore 67). The rigidity of the material forming the second portion 246 is higher than the rigidity of the material forming the first portion 244 and, as such, when the impactor Q impacts the display surface 100a on the center line S1 that passes through the center P0 of the display region 112 and that is perpendicular to the display region 112, the rigidity of the +X side (the second portion 246) with respect to the center line S1 is higher than the rigidity of the −X side (the first portion 244) with respect to the center line S1. That is, when the impactor Q impacts the display surface 100a on the center line S1 that passes through the center P0 of the display region 112 and that is perpendicular to the display region 112, the rigidity to impact of the holder 200 (the display device 10) fixed to the instrument panel 500 is asymmetrical.

Furthermore, as illustrated in FIG. 21, a width D4 in one direction (the X direction) of the opening on the display 100 side of the open section 240 is less than the maximum width QD in the one direction (the X direction) of the impactor Q. Due to this, the impactor Q can be prevented from penetrating the display device 10.

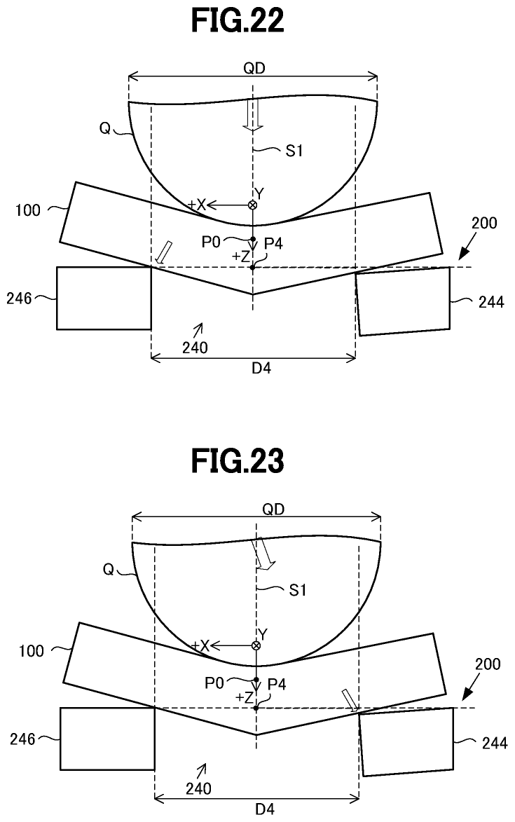

Next, the deceleration of the impactor Q in a case in which the impactor Q impacts the center P1 of the display surface 100a is described while referencing FIGS. 22 and 23. The deceleration of the impactor Q is described for an example of a case in which the spherical impactor Q moves on the center line S1 from the −Z side and impacts the display surface 100a on the center line S1.

When the impactor Q impacts the display surface 100a (the impact position P1) on the center line S1, the rigidity of the second portion 246 (the +X side) of the holder 200 is higher than the rigidity of the first portion 244 (the −X side) of the holder 200 and, as such, as illustrated in FIG. 22, the load caused by the impactor Q is mainly applied to the second portion 246 side, and the first portion 244 deforms. As a result, as in Embodiment 1, both +Z direction deceleration and +X direction deceleration occur. Next, the impactor Q moves to the deformed first portion 244 side and, as illustrated in FIG. 23, the load caused by the impactor Q is mainly applied to the first portion 244 side. As a result, as in Embodiment 1, both +Z direction deceleration and −X direction deceleration occur. Specifically, as with Embodiment 1, in the present embodiment as well, the direction in which the load is mainly applied changes with the passage of time, and the X direction deceleration fluctuates from the +X direction to the −X direction. Accordingly, as with the display device 10 of Embodiment 1, the display device 10 of the present embodiment can shorten the amount of time in which the deceleration of the impactor Q is great.

As described above, the first portion 244 and the second portion 246 of the holder 200 are formed from materials having mutually different rigidities and, as such, when the impactor Q impacts the display surface 100a on the center line S1 that passes through the center P0 of the display region 112 and that is perpendicular to the display region 112, the rigidity to impact of the display device 10 (the holder 200) fixed to the instrument panel 500 is asymmetrical. Due to this, the display device 10 can shorten the amount of time in which the deceleration of the impactor Q is great.

### Embodiment 5

In Embodiment 1 to Embodiment 4, the display device 10 includes one holder 200. However, a configuration is possible in which the display device 10 includes a plurality of holders 310.

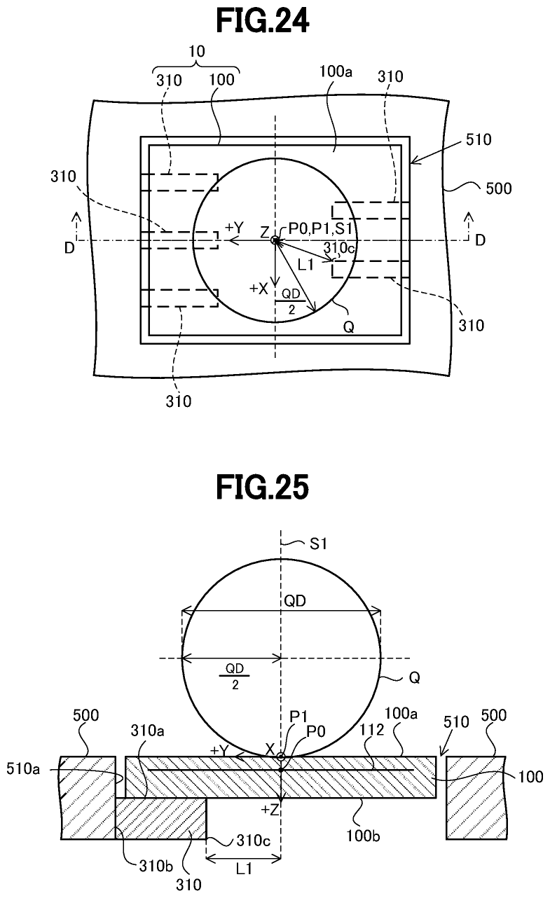

As illustrated in FIG. 24, the display device 10 of the present embodiment includes the display 100 and five holders 310. As with the holder 200 of Embodiment 1, the holders 310 fix the display 100 in the open section 510 of the instrument panel 500. The configuration of the display 100 of the present embodiment is the same as that of the display 100 of Embodiment 1 and, as such, the holders 310 are described.

Each of the holders 310 has a parallelepiped shape. The holders 310 are formed from a resin or a metal. As illustrated in FIG. 25, the holders 310 are provided on the surface 100b (the bottom surface 133 of the chassis 132) of the display 100 by an adhesive. In the present embodiment, a portion of a top surface 310a of each of the holders 310 is adhered to the surface 100b of the display 100 by the adhesive. Additionally, a side surface 310b of each of the holders 310 is adhered to the inner wall 510a of the open section 510 of the instrument panel 500 by the adhesive.

When viewing the display device 10 from above, the five holders 310 are disposed asymmetrical with respect to the center line S1 that passes through the center P0 of the display region 112 and that is perpendicular to the display region 112. Specifically, as illustrated in FIG. 24, three of the holders 310 are disposed on the +Y-side end of the display 100, and two of the holders 310 are disposed on the −Y-side end of the display 100. In the present embodiment, the five holders 310 are disposed asymmetrical with respect to the center line S1 that passes through the center P0 of the display region 112 and that is perpendicular to the display region 112 and, as such, when the impactor Q impacts the display surface 100a on the center line S1 that passes through the center P0 of the display region 112 and that is perpendicular to the display region 112, the rigidity to impact of the display device 10 fixed to the instrument panel 500 is asymmetrical.

As illustrated in FIG. 24, when viewing the display device 10 from above, a distance L1 from an end 310c of each of the holders 310 to the center P0 of the display region 112 is less than half (QD/2) the maximum width QD of the impactor Q. Due to this, the impactor Q can be prevented from penetrating the display device 10. Note that the distance L1 from the end 310c of each of the holders 310 to the center P0 of the display region 112 can be adjusted by adjusting the length (the Y direction length) of the holders 310, the arrangement of the holders 310, and the like.

In the present embodiment as well, when the impactor Q impacts the display surface 100a on the center line S1 that passes through the center P0 of the display region 112 and that is perpendicular to the display region 112, the rigidity to impact of the display device 10 fixed to the instrument panel 500 is asymmetrical and, as such, the display device 10 of the present embodiment can shorten the amount of time in which the deceleration of the impactor Q is great.

### Embodiment 6

In Embodiment 5, the display device 10 includes the plurality of holders 310. A configuration is possible in which the display device 10 includes pluralities of holders 322 and 324 that have different sizes.

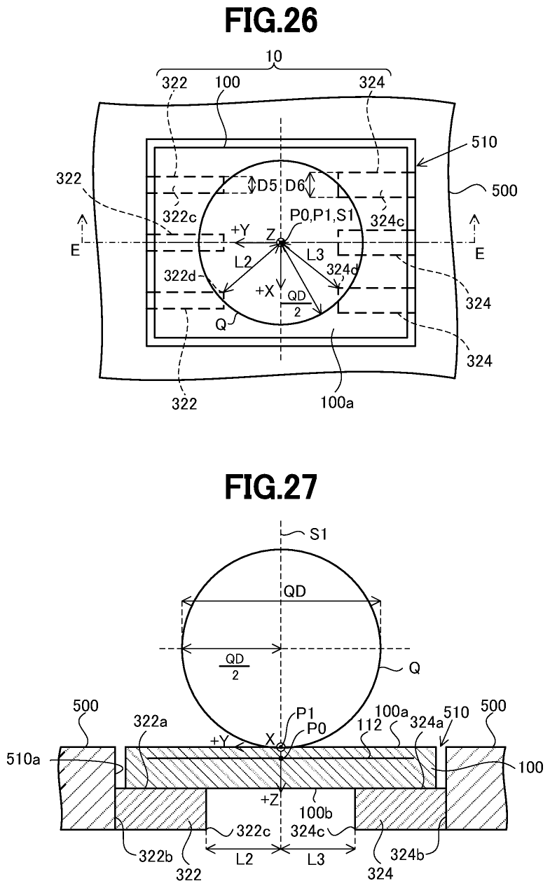

As illustrated in FIG. 26, the display device 10 of the present embodiment includes the display 100, three holders 322, and three holders 324. As with the holder 200 of Embodiment 1, the holders 322 and 324 fix the display 100 in the open section 510 of the instrument panel 500. The configuration of the display 100 of the present embodiment is the same as that of the display 100 of Embodiment 1 and, as such, the holders 322 and 324 are described.

Each of the holders 322 and 324 has a parallelepiped shape and is formed from a resin or a metal. In the present embodiment, as illustrated in FIG. 26, a width (X direction length) D6 of the holders 324 is greater than a width (X direction length) D5 of the holders 322. Additionally, a hereinafter described area of a surface 324c of the holders 324 that hold the display 100 is greater than a hereinafter described area of a surface 322c of the holders 322 that hold the display 100. Note that a length (Y direction length) of the holders 322 and a length (Y direction length) of the holders 324 are the same.

When viewing the display device 10 from above, the three holders 322 are disposed on the +Y-side end of the display 100, and the three holders 324 are disposed on the −Y-side end of the display 100. The holders 322 and the holders 324 oppose each other on a one-to-one basis.

As illustrated in FIG. 27, the holders 322 and 324 are provided on the surface 100b (the bottom surface 133 of the chassis 132) of the display 100. In the present embodiment, a portion of a top surface 322a of each of the holders 322 is adhered to the surface 100b of the display 100, and a portion of a top surface 324a of each of the holders 324 is adhered to the surface 100b of the display 100. The portion of the top surface 322a of each of the holders 322 that is adhered to the surface 100b of the display 100 corresponds to the surface 322c of each of the holders 322 that holds the display 100. The portion of the top surface 324a of each of the holders 324 that is adhered to the surface 100b of the display 100 corresponds to the surface 324c of each of the holders 324 that holds the display 100.

Additionally, a side surface 322b of each of the holders 322 is adhered to the inner wall 510a of the open section 510 of the instrument panel 500. A side surface 324b of each of the holders 324 is adhered to the inner wall 510a of the open section 510 of the instrument panel 500.

In the present embodiment, the area of the surface 324c of the holders 324 that hold the display 100 is greater than the area of the surface 322c of the holders 322 that hold the display 100. Furthermore, the holders 322 are disposed on the +Y-side end of the display 100, and the holders 324 are disposed on the −Y-side end of the display 100. Accordingly, when the impactor Q impacts the display surface 100a on the center line S1 that passes through the center P0 of the display region 112 and that is perpendicular to the display region 112, the rigidity to impact of the display device 10 fixed to the instrument panel 500 is asymmetrical. In the following, the holders 322 and the holders 324 are sometimes referred to collectively as holders 320.

Furthermore, as illustrated in FIG. 26, when viewing the display device 10 from above, distances L2 and L3 between ends 322d and 324d of the holders 322 and 324, respectively, and the center P0 of the display region 112 is less than half (QD/2) the maximum width QD of the impactor Q. Due to this, the impactor Q can be prevented from penetrating the display device 10. The distances L2 and L3 can be adjusted by respectively adjusting the lengths of the holders 322 and 324, the arrangement of the holders 322 and 324, and the like.

In the present embodiment, the rigidity to impact of the display device 10 fixed to the instrument panel 500 is asymmetrical and, as such, the display device 10 of the present embodiment can shorten the amount of time in which the deceleration of the impactor Q is great. Accordingly, the display device 10 of the present embodiment also can enhance rider safety.

### Embodiment 7

In Embodiment 1 to Embodiment 6, the holders 200 to 324 fix the display 100 to the instrument panel 500 of a vehicle. A configuration is possible in which the holder fixes the display 100 to an instrument panel reinforcement (hereinafter referred to as “IPR”) of a vehicle. The IPR is a frame member of the vehicle, and supports the instrument panel 500 from behind.

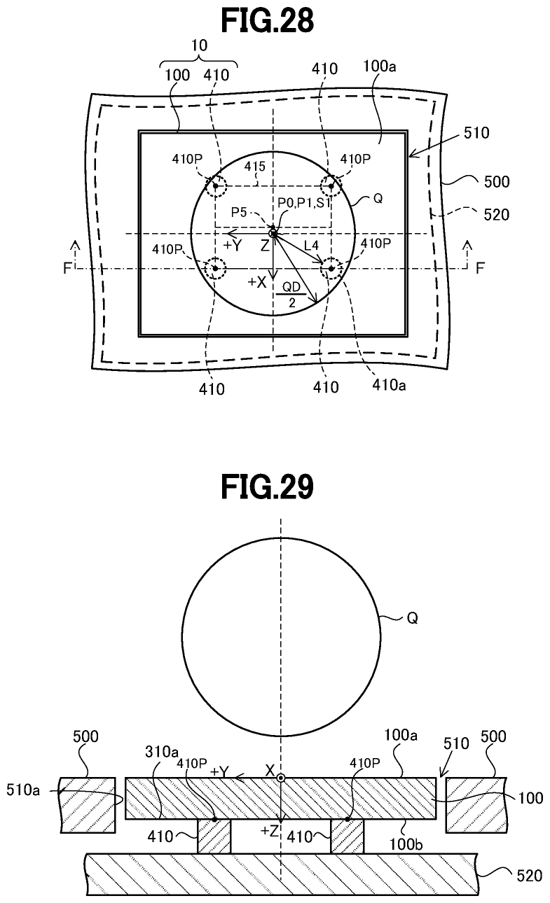

As illustrated in FIG. 28, the display device 10 of the present embodiment includes the display 100, and four holders 410. The display 100 of the present embodiment is disposed in the open section 510 of the instrument panel 500. The holders 410 fix the display 100 to an IPR 520 positioned on the side of the display 100 opposite the display surface 100a. The IPR 520 corresponds to the fixing target. The configuration of the display 100 of the present embodiment is the same as that of the display 100 of Embodiment 1 and, as such, the holders 410 are described.

The holders 410 are formed in a round columnar shape from a resin or a metal. As illustrated in FIG. 29, the holders 410 are provided on the surface 100b (the bottom surface 133 of the chassis 132) of the display 100. The holders 410 fix the display 100 to the IPR 520. A −Z-side surface of each of the holders 410 is adhered to the surface 100b of the display 100. A +Z-side surface of each of the holders 410 is adhered to the IPR 520.

When viewing the display device 10 from above, as illustrated in FIG. 28, a region surrounded by line segments connecting centers 410P on the −Z-side surface of each of the four holders 410 forms a quadrangle (a rectangle in the present embodiment) 415, and a position of a center P5 of the formed quadrangle 415 is disposed at a position offset in the −X direction from the position of the center P0 of the display region 112. Furthermore, when viewing the display device 10 from above, each of the holders 410 is positioned at a position at which a shortest distance L4 from the center P0 of the display region 112 to an outer circumferential surface 410a of each of the holders 410 is shorter than half (QD/2) the maximum width QD of the impactor Q.

In the present embodiment, when viewing the display device 10 from above, the position of the center P5, of the region of the quadrangle 415 formed by connecting the centers 410P of the four holders 410 with line segments, is offset from the position of the center P0 of the display region 112 and, as such, when the impactor Q impacts the display surface 100a on the center line S1 that passes through the center P0 of the display region 112 and that is perpendicular to the display region 112, the rigidity to impact of the display device 10 fixed to the IPR 520 is asymmetrical. Additionally, the shortest distance L4 from the center P0 of the display region 112 to the outer circumferential surface 410a of each of the holders 410 is shorter than half (QD/2) the maximum width QD of the impactor Q and, as such, the display device 10 can prevent penetration of the impactor Q.

In the present embodiment as well, when the impactor Q impacts the display surface 100a on the center line S1 that passes through the center P0 of the display region 112 and that is perpendicular to the display region 112, the rigidity to impact of the display device 10 fixed to the IPR 520 is asymmetrical and, as such, the display device 10 of the present embodiment can shorten the amount of time in which the deceleration of the impactor Q is great. Accordingly, the display device 10 of the present embodiment also can enhance rider safety.

### Embodiment 8

In Embodiment 1 to Embodiment 7, the rigidity to impact of the display device 10 is asymmetrical due to the configuration of the holders 200 to 410. A configuration is possible in which the rigidity to impact is asymmetrical due to the configuration of the display 100 of the display device 10.

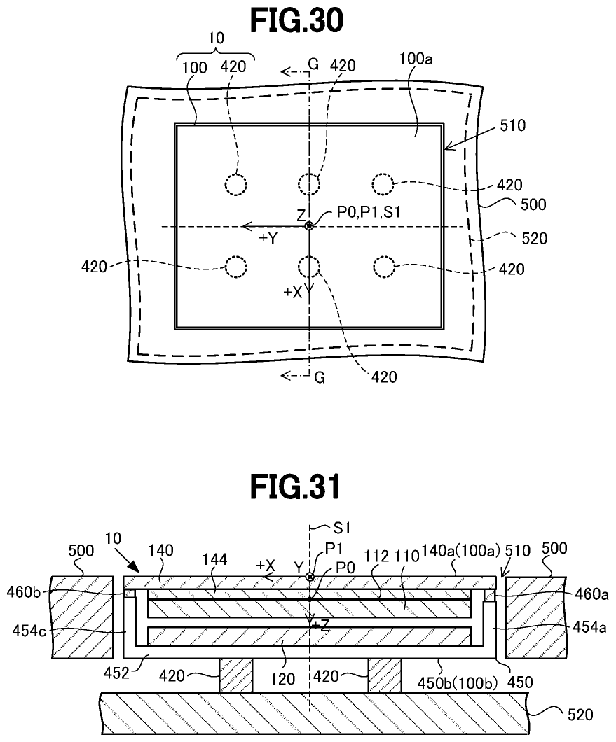

As illustrated in FIG. 30, the display device 10 of the present embodiment includes the display 100, and six holders 420. The display 100 of the present embodiment is disposed in the open section 510 of the instrument panel 500. As with the holders 410 of Embodiment 7, the holders 420 fix the display 100 to the IPR 520.

As illustrated in FIG. 31, the display 100 of the present embodiment is fixed to the IPR 520 by the holders 420. The display 100 of the present embodiment includes the liquid crystal display panel 110, the back light 120, a housing 450, and a cover 140. The liquid crystal display panel 110 and the back light 120 of the present embodiment are the same as the liquid crystal display panel 110 and the back light 120 of Embodiment 1 and, as such, the housing 450 and the cover 140 of the present embodiment are described.

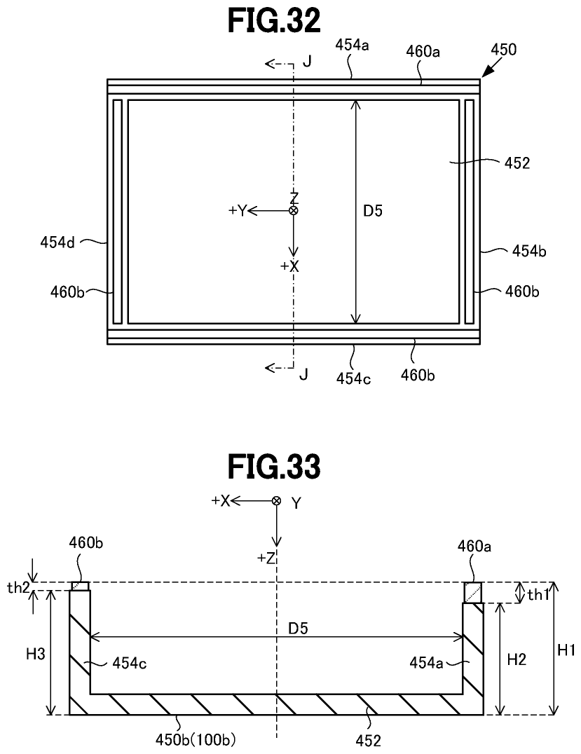

The housing 450 of the present embodiment has a box-like shape, and is formed from a resin or a metal. The housing 450 accommodates, on an inner side thereof, the liquid crystal display panel 110 and the back light 120. As illustrated in FIG. 32, the housing 450 includes a bottom plate 452, and side plates 454a to 454d.

The bottom plate 452 is a flat plate that has a rectangular shape. As illustrated in FIG. 31, the back light 120 is disposed on the bottom plate 452. The +Z-side surface 450b of the bottom plate 452 corresponds to the surface 100b on the side opposite the display surface 100a of the display 100.

The side plates 454a to 454d surround the liquid crystal display panel 110 and the back light 120. As illustrated in FIG. 32, the side plate 454a extends in the Y direction and is positioned on the −X side, and the side plate 454c extends in the Y direction and is positioned on the +X side. The side plate 454a and the side plate 454c oppose each other in the X direction with the liquid crystal display panel 110 and the back light 120 therebetween. Additionally, the side plate 454b extends in the X direction and is positioned on the −Y side, and the side plate 454d extends in the X direction and is positioned on the +Y side. The side plate 454b and the side plate 454d oppose each other in the Y direction with the liquid crystal display panel 110 and the back light 120 therebetween.

In order to provide the cover 140 on the side plates 454a to 454d of the housing 450, an adhesive member 460a is provided on a top surface (−Z-side surface) of the side plate 454a, and an adhesive member 460b is provided on a top surface (−Z-side surface) of the side plates 454b to 454d. In the present embodiment, a thickness th1 of the adhesive member 460a is, as illustrated in FIG. 33, greater than a thickness th2 of the adhesive member 460b. In one example, the thickness th1 of the adhesive member 460a is 1 mm, and the thickness th2 of the adhesive member 460b is 0.2 mm. The adhesive members 460a and 460b are implemented as double-sided tape, an adhesive, or the like. Note that, in the present embodiment, in order to make the sum of the thickness th1 of the adhesive member 460a and a height H2 of the side plate 454a, and the sum of the thickness th2 of the adhesive member 460b and a height H3 of the side plates 454b to 454d match the height H1, the height H2 of the side plate 454a is lower than the height H3 of the side plates 454b to 454d.

The cover 140 of the present embodiment is provided on the side plates 454a to 454d of the housing 130 via the adhesive members 460a and 460b. In the present embodiment, as illustrated in FIG. 31, the liquid crystal display panel 110 is affixed to the cover 140 by the light-transmitting adhesive 144. The other configurations of the cover 140 of the present embodiment are the same as the cover 140 of Embodiment 1. In the following, the adhesive member 460a and the adhesive member 460b are sometimes referred to collectively as adhesive members 460.

The holders 420 are formed in a round columnar shape from a resin or a metal. As illustrated in FIG. 31, the holders 410 are provided on the surface 100b (the surface 450b of the housing 450) of the display 100, and fix the display 100 to the IPR 520. The −Z-side surface of each of the holders 420 is adhered to the surface 100b of the display 100. The +Z-side surface of each of the holders 410 is adhered to the IPR 520.

When viewing the display device 10 from above, as illustrated in FIG. 30, the six holders 420 are arranged in two rows of three holders 420 along the Y direction. Additionally, the six holders 420 are positioned symmetrical to the X axis and the Y axis. The holders 420 symmetrically support the display 100 with respect to the center P0 of the display region 112.

In the present embodiment, the holders 420 symmetrically support the display 100 with respect to the center P0 of the display region 112. Additionally, the thickness th1 of the adhesive member 460a that adheres the cover 140 of the display 100 to the side plate 454a of the housing 450 of the display 100, and the thickness th2 of the adhesive member 460b that adheres the cover 140 of the display 100 to the side plate 454c of the housing 450 of the display 100 differ. Accordingly, when the impactor Q impacts the display surface 100a on the center line S1 that passes through the center P0 of the display region 112 and that is perpendicular to the display region 112, the rigidity to impact of the display device 10 fixed to the IPR 520 is asymmetrical (asymmetrical in the X direction).

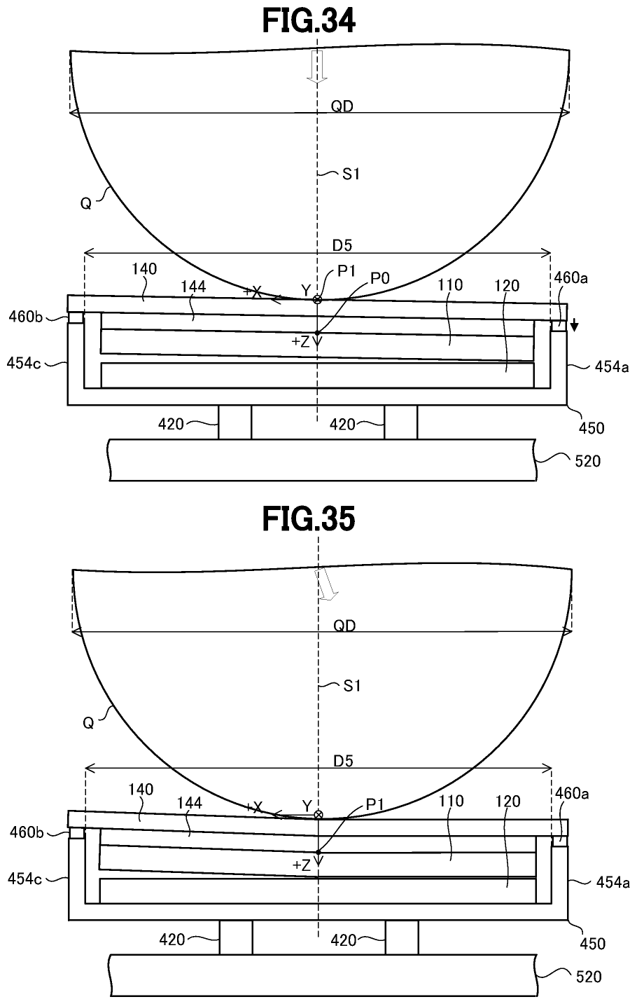

Next, the deceleration of the impactor Q in a case in which the impactor Q impacts the center P1 of the display surface 100a is described while referencing FIGS. 34 and 35. The deceleration of the impactor Q is described for an example of a case in which the spherical impactor Q moves on the center line S1 from the −Z side and impacts the display surface 100a on the center line S1.

When the impactor Q impacts the display surface 100a (the impact position P1) on the center line S1, the load caused by the impactor Q is applied in the +Z direction to the display device 10 and, as such, +Z direction deceleration occurs. In this case, the thickness th1 of the adhesive member 460a on the side plate 454a of the housing 450 is greater than the thickness th2 of the adhesive member 460b on the side plate 454c of the housing 450 and, as such, as illustrated in FIG. 34, the adhesive member 460a is greatly compressed, and the cover 140, and the liquid crystal display panel 110 and the back light 120 affixed to the cover 140 incline to the side plate 454a side (the −X direction side). As a result, the impactor Q moves to the side plate 454a side and, as illustrated in FIG. 35, the load caused by the impactor Q is applied mainly to the side plate 454a side and, as such, both +Z direction deceleration and −X direction (side plate 454a side) deceleration occur. In the present embodiment as well, the direction in which the load is mainly applied changes with the passage of time, and the X direction deceleration fluctuates. Accordingly, as with the display device 10 of Embodiment 1, the display device 10 of the present embodiment can shorten the amount of time in which the deceleration of the impactor Q is great.

In the present embodiment, as illustrated in FIGS. 34 and 35, it is preferable that a width D5 in one direction (the X direction) of the housing 450 is narrower than the maximum width QD in the one direction (the X direction) of the impactor Q. Due to this, the impactor Q can be prevented from penetrating the display device 10.

As described above, the thickness th1 of the adhesive member 460a and the thickness th2 of the adhesive member 460b differ and, as such, when the impactor Q impacts the display surface 100a on the center line S1 that passes through the center P0 of the display region 112 and that is perpendicular to the display region 112, the rigidity to impact of the display device 10 fixed to the IPR 520 is asymmetrical (asymmetrical in the X direction). Additionally, in the present embodiment as well, the direction in which the load is mainly applied changes and the X direction deceleration fluctuates and, as such, the display device 10 of the present embodiment can shorten the amount of time in which the deceleration of the impactor Q is great.

### Embodiment 9

It is preferable that the holders 200 to 420 are formed from a material having low rigidity or hardness. In the present embodiment, the material forming the holder 200 and the deceleration of the impactor Q in a display device 10 having the same form (same dimensions) as the specific example of Embodiment 1 illustrated in FIGS. 11 and 12 are described.

In the present embodiment, the holder 200 is formed from stainless steel (Young's modulus: 193 GPa, hardness: Shore 67), urethane rubber (Young's modulus: 40 MPa, hardness: Shore A70), or silicon rubber (Young's modulus: 4 MPa, hardness: Asker C35). Note that the offset α between the center P0 of the display region 112 and the center P2 of the opening is 2 mm. The holder 200 has a thickness th3 of 10 mm.

As in the specific example of Embodiment 1, in the present embodiment, the display device 10 was fixed in the open section 510 of the instrument panel 500. Then, an impact tester was used to cause the spherical impactor Q having a diameter (maximum width) QD of 165 mm and a weight of 6.8 kg to move at 24.1 km/h on the center line S1 from the −Z side and impact the display surface 100a (the impact position P1) on the center line S1.

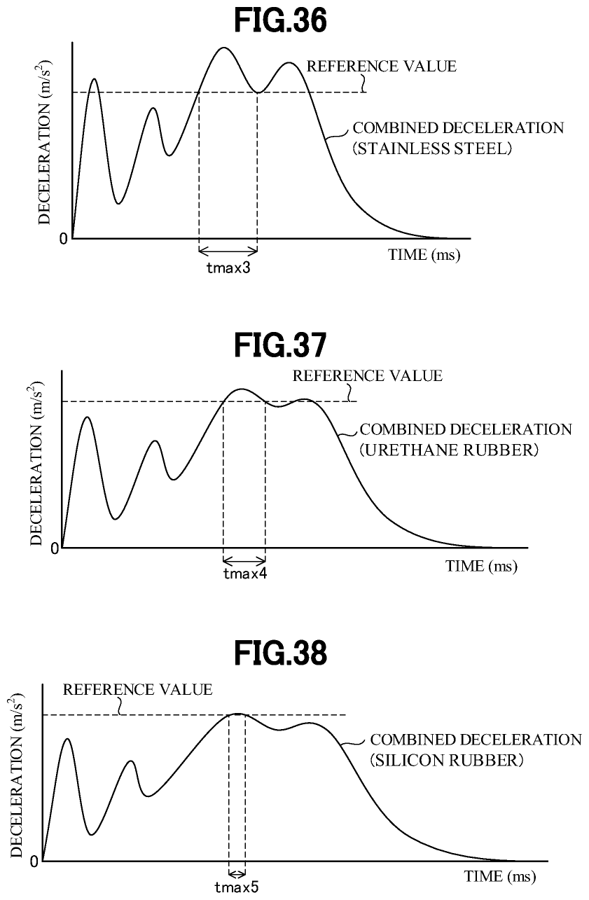

FIG. 36 illustrates the deceleration of the impactor Q in the display device 10 in which the holder 200 is formed from the stainless steel. FIG. 37 illustrates the deceleration of the impactor Q in the display device 10 in which the holder 200 is formed from the urethane rubber. FIG. 38 illustrates the deceleration of the impactor Q in the display device 10 in which the holder 200 is formed from the silicon rubber.

A longest amount of time tmax3 (FIG. 36) of the amounts of time in which the combined deceleration continuously exceeds the reference value in the display device 10 in which the holder 200 is formed from the stainless steel is set as 100%. A longest amount of time tmax4 (FIG. 37) of the amounts of time in which the combined deceleration continuously exceeds the reference value in the display device 10 in which the holder 200 is formed from the urethane rubber was 88% of tmax3. A longest amount of time tmax5 (FIG. 38) of the amounts of time in which the combined deceleration continuously exceeds the reference value in the display device in which the holder 200 is formed from the silicon rubber was 16% of tmax3.

As described above, the display device 10 including the holder 200 formed from the material having low rigidity or hardness (stainless steel>urethane rubber>silicon rubber) can further shorten the amount of time in which the deceleration of the impactor Q is great. Accordingly, the display device 10 including the holder 200 formed from the material having low rigidity or hardness can further enhance rider safety. Note that the amount of time for the deceleration of the impactor Q to decrease to zero increases as the rigidity or the hardness of the material forming the holder 200 decreases (FIGS. 36 to 38).

### Embodiment 10

In the present embodiment, the deceleration of the impactor Q in a configuration in which the rigidity of the fixing target is greater than the rigidity of the holder 200 is described for an example of a display device 10 fixed to a bottom surface 512 of a box-shaped instrument panel 500.

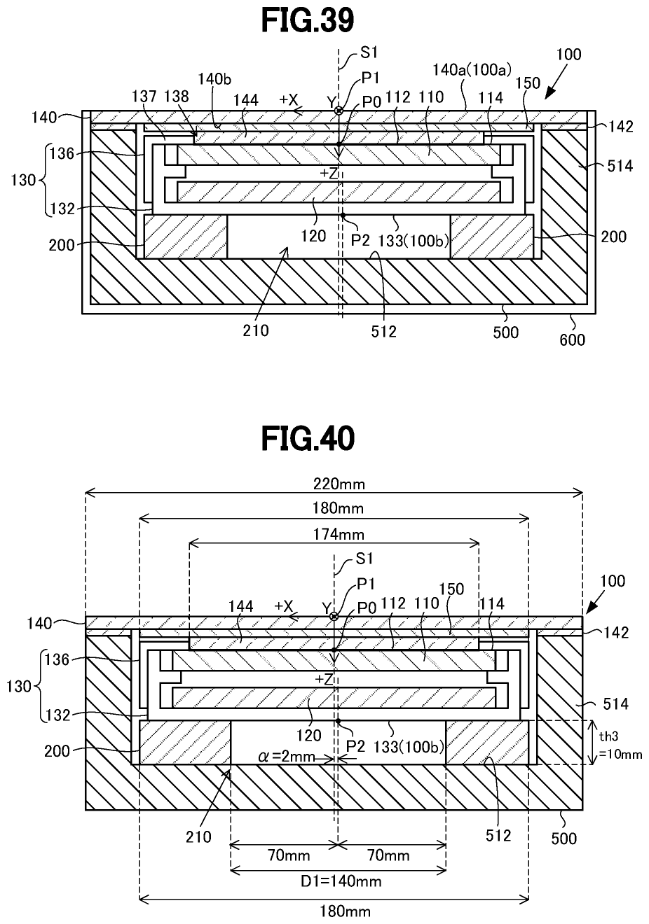

The instrument panel 500 of the present embodiment is formed in a box-shape that is open on the +Z side. The instrument panel 500 is formed by aluminum die casting using an aluminum alloy (for example, ADC12). The Young's modulus of ADC12 is 71 GPa. The Rockwell hardness of ADC12 is 54 in HRB. As illustrated in FIG. 39, the instrument panel 500 of the present embodiment accommodates, on an inner side thereof, the liquid crystal display panel 110, the back light 120, the holder 200, and the like of the display device 10.

In the present embodiment, the outer peripheries of the instrument panel 500 and the cover 140 of the display device 10 are covered by a surface material 600. In one example, the surface material 600 is formed from resin. The color of the surface material 600 and the color of the cover 140 are the same. The surface material 600 is provided on the outer peripheries of the instrument panel 500 and the cover 140 by adhesion, screwing, or the like. The color of the surface material 600 covering the outer peripheries of the instrument panel 500 and the cover 140 and the color of the cover 140 are the same and, as such, a sense of unity of the instrument panel 500 and the display device 10 can be enhanced.

As with the display device 10 of Embodiment 1, the display device 10 of the present embodiment includes the display 100 and the holder 200. The display 100 displays characters, images, and the like. The holder 200 fixes the display device 10 to the bottom surface 512 of the inside of the instrument panel 500.

The display 100 of the present embodiment further includes a touch panel 150 in addition to the liquid crystal display panel 110, the back light 120, the housing 130, and the cover 140. The touch panel 150 is provided on the +Z-side surface 140b of the cover 140 by a non-illustrated adhesive layer. In one example, the touch panel 150 is implemented as a capacitive touch panel. The touch panel 150 detects the position at which the rider contacts the cover 140.

In the present embodiment, space between the liquid crystal display panel 110 and the touch panel 150 provided on the cover 140 is filled with the adhesive 144.

The cover 140 of the present embodiment is affixed to a top surface of a side wall 514 of the instrument panel 500 by the adhesive member 142. Accordingly, the cover 140 of the present embodiment is supported, by the side wall 514 of the instrument panel 500, from the opposite side (the −Z side) of the direction in which the impactor Q impacts.

The other configurations of the display 100 of the present embodiment are the same as the display 100 of Embodiment 1.

As with the holder 200 of Embodiment 1, the holder 200 of the present embodiment has a frame-like shape, and a rectangular open section 210 is provided in a center section of the holder 200. The holder 200 of the present embodiment is formed from urethane rubber (Young's modulus: 40 MPa, hardness: Shore A70) or silicon rubber (Young's modulus: 4 MPa, hardness: Asker C35).

The holder 200 of the present embodiment is provided, by an adhesive, on the surface 100b (the bottom surface 133 of the chassis 132) on the side opposite the display surface 100a of the display 100. The holder 200 of the present embodiment fixes the display device 10 (the display 100) to the bottom surface 512 of the inside of the instrument panel 500 via an adhesive. The instrument panel 500 has a box-like shape that is open on the +Z side, and the holder 200 fixes the display device 10 to the bottom surface 512 of the inside of the instrument panel 500. As such, the display device 10 (the display 100) is supported, via the holder 200, by the bottom surface 512 from the opposite side (the −Z side) of the direction in which the impactor Q impacts.

As with the holder 200 of Embodiment 1, with the holder 200 of the present embodiment, the position of the center P2 of the opening on the display 100 side (the −Z side) of the open section 210 is offset in the −X direction from the position of the center P0 of the display region 112. In the present embodiment, the offset α between the position of the center P0 of the display region 112 and the position of the center P2 of the opening is 2 mm.

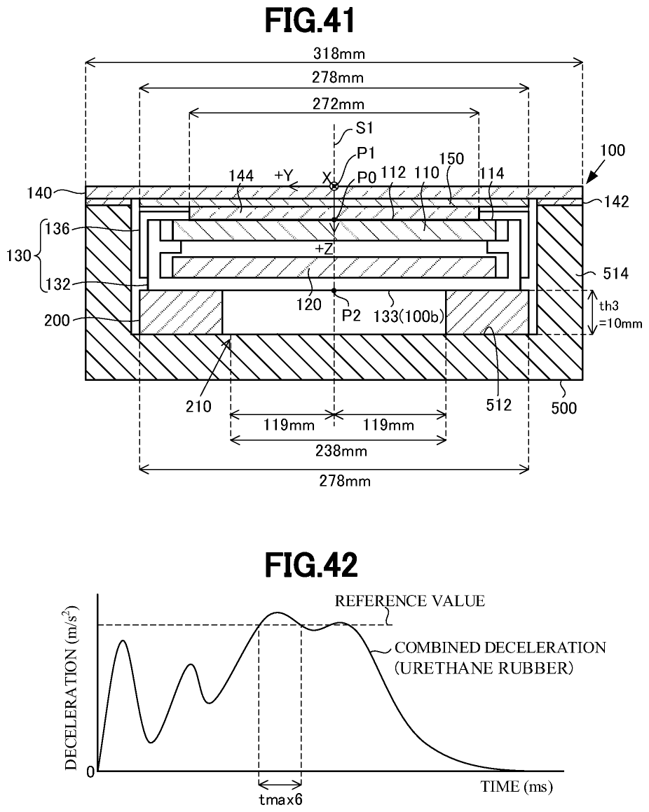

Next, the deceleration of the impactor Q is described. In one example, the various components of the display device 10 of the present embodiment have the dimensions illustrated in FIGS. 40 and 41. With the exception of the external forms of the cover 140, the touch panel 150, and the holder 200, and the thickness th3 of the holder 200, the dimensions of the various components are the same as the dimensions of the specific example of Embodiment 1 (external form of the cover 140: 220 mm×318 mm, external form of the touch panel 150: 180 mm×278 mm, external form of the holder 200: 180 mm×278 mm, and thickness th3 of the holder 200: 10 mm). For the display device 10 fixed to the bottom surface 512, as in the specific example of Embodiment 1, an impact tester was used to cause the spherical impactor Q having a diameter (maximum width) QD of 165 mm and a weight of 6.8 kg to move at 24.1 km/h on the center line S1 from the −Z side and impact the display surface 100a (the impact position P1) on the center line S1.

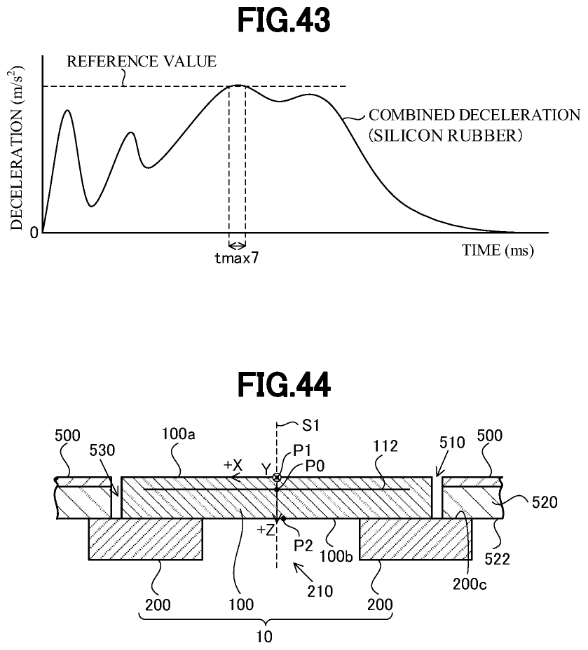

FIG. 42 illustrates the deceleration of the impactor Q in the display device 10 in which the holder 200 is formed from the urethane rubber. FIG. 43 illustrates the deceleration of the impactor Q in the display device 10 in which the holder 200 is formed from the silicon rubber.

An amount of time tmax3 in which the combined deceleration continuously exceeds the reference value in Embodiment 9 is set as 100%. A longest amount of time tmax6 (FIG. 42) of the amounts of time in which the combined deceleration continuously exceeds the reference value in the display device 10 in which the holder 200 is formed from the urethane rubber was 88% of tmax3, as with the display device 10 in which the holder 200 is formed from the urethane rubber of Embodiment 9. A longest amount of time tmax7 (FIG. 43) of the amounts of time in which the combined deceleration continuously exceeds the reference value in the display device 10 in which the holder 200 is formed from the silicon rubber was 16% of tmax3, as with the display device 10 in which the holder 200 is formed from the silicon rubber of Embodiment 9. Accordingly, in the present embodiment as well, the display device 10 including the holder 200 formed form the material having low rigidity or hardness can further shorten the amount of time in which the deceleration of the impactor Q is great.

When the display device 10 includes the touch panel 150 and the rigidity of the holder 200 is low, the sense of contact of the rider on the touch panel 150 decreases due to the deformation of the holder 200, and the operability of the touch panel 150 may decline. In the present embodiment, the instrument panel 500 formed from the material having higher rigidity than the rigidity of the material forming the holder 200 supports the display device 10 from the opposite side of the impact direction of the impactor Q (that is, the direction of the rider) and, as such, the amount of time in which the deceleration of the impactor Q is great can be shortened without negatively affecting the operability of the touch panel 150. That is, it is preferable that the rigidity of the instrument panel 500 is greater than the rigidity of the holder 200.

Note that it is preferable that the thickness th3 of the holder 200 is a thickness that does not exceed the limit of compressive deformation of the holder 200 when the impactor Q impacts. When the limit of compressive deformation of the holder 200 is exceeded due to the impact of the impactor Q, the amount of time in which the deceleration of the impactor Q is great may increase due to the rigidity of the instrument panel 500. It is preferable that in the holder 200 formed from the silicon rubber of the present embodiment, for example, the thickness th3 of the holder 200 is 3 mm or greater.

### Modified Examples

Embodiments have been described, but various modifications can be made to the present disclosure without departing from the spirit and scope of the present disclosure.

For example, in the embodiments, the holders 200 to 420 are provided on the housing 130 (the chassis 132), 450 of the display 100 by adhesion. However, a configuration is possible in which the holders 200 to 420 are provided on the housing 130 (the chassis 132), 450 of the display 100 by screwing, welding, and the like. Additionally, a configuration is possible in which the holders 200 to 420 and the housing 130 (the chassis 132), 450 are formed integrally.

In the embodiments, the holders 200 to 420 are adhered to the instrument panel 500 or the IPR 520. However, a configuration is possible in which the holders 200 to 420 are screwed to the instrument panel 500 or the IPR 520.

In the embodiments, the display 100 includes the cover 140. However, a configuration is possible in which the display 100 does not include the cover 140. When the display 100 does not include the cover 140, the surface of the −Z side (the rider side) of the liquid crystal display panel 110 corresponds to the display surface 100a of the display 100.

In the embodiments, the display 100 includes the liquid crystal display panel 110 and the back light 120. However, a configuration is possible in which the display 100 includes another display panel (display device). For example, a configuration is possible in which the display 100 includes an organic electro-luminescence (EL) display panel instead of the liquid crystal display panel 110 and the back light 120.

In the embodiments, the display 100 is disposed in the open section 510 of the instrument panel 500. However, the position of the display 100 is not limited to the open section 510 of the instrument panel 500. For example, as illustrated in FIG. 44, a configuration is possible in which the display 100 of the display device 10 of Embodiment 1 is disposed straddling the open section 510 of the instrument panel 500 and an open section 530 of the IPR 520. In such a case, a surface 200c on the display 100 side of the holder 200 is adhered to a back surface 522 of the IPR 520.

In Embodiments 1 to 3, the position of the center P0 of the display region 112 is offset in the −X direction from the positions of the center P2 of the opening of the open section 210 and the center P3 of the opening of the recess 220, 230. The direction in which the position of the center P0 of the display region 112 is offset from the positions of the center P2 of the opening of the open section 210 and the center P3 of the opening of the recess 220, 230 can be set to any direction. For example, a configuration is possible in which the position of the center P0 of the display region 112 is offset in the −Y direction from the positions of the center P2 of the opening of the open section 210 and the center P3 of the opening of the recess 220, 230.

In Embodiments 1 and 4, the open section 210, 240 is formed in a rectangular shape. However, a configuration is possible in which, as with the recess 230 of Embodiment 3, in the open section 210, 240, the width in one direction (the X direction) becomes narrower toward the direction opposite the display 100 (the +Z direction). In such a case, the minimum width in the one direction (the X direction) of the open section 210, 240 is less than the maximum width QD in the one direction (the X direction) of the impactor Q. Additionally, the direction in which the minimum width of the open section 210, 240 is less than the maximum width QD of the impactor Q is not limited to the X direction and can be any direction. For example, a configuration is possible in which the minimum width in the Y direction of the open section 210 is less than the maximum width (diameter) QD in the Y direction of the impactor Q.

The cross-sectional shape of the recess 230 of Embodiment 3 is not limited to the trapezoid shape. A configuration is possible in which the cross-sectional shape of the recess 230 is a V-shape, for example.

In Embodiment 3 as well, the direction in which the minimum width of the recess 230 is less than the maximum width QD of the impactor Q is not limited to the X direction and can be any direction.

In the holder 200 of Embodiment 4, the rigidity of the first portion 244 and the rigidity of the second portion 246 differ, and the first portion 244 and the second portion 246 oppose each other in the X direction. It is sufficient that the first portion 244 and the second portion 246 oppose each other, and a configuration is possible in which the first portion 244 and the second portion 246 oppose each other in the Y direction.

It is sufficient that the holders 310 of Embodiment 5 are disposed asymmetrical to the center line S1. For example, a configuration is possible in which the holders 310 are disposed on the +Y-side end, the −Y-side end, and the +X-side end of the display 100.

In Embodiment 6, it is sufficient that the area of the surface, holding the display 100, of at least one of the holders 320 differs from the area of the surface, holding the display 100, of the other holders 320.

In Embodiment 7, the holders 410 are formed in a round columnar shape. Additionally, when viewing the display device 10 from above, the region surrounded by line segments that connect the centers 410P of the four holders 410 forms the quadrangle 415, and the position of the center P5 of the formed quadrangle 415 is offset from the position of the center P0 of the display region 112. However, a configuration is possible in which the holders 410 have a quadrangular prism shape, a truncated cone shape, or the like. The number of holders 410 is not limited to four. It is sufficient that, when viewing the display device 10 from above, the region surrounded by line segments that connect the centers 410P of the plurality of holders 410 forms a polygon, and the center of the polygon is offset from the position of the center P0 of the display region 112. For example, a configuration is possible in which a pentagonal region is formed from five of the holders 410.

In Embodiment 8, it is sufficient that the thicknesses of the adhesive members 460 that oppose each other with the liquid crystal display panel 110 and the back light 120 therebetween differ. Additionally, the direction in which the width of the housing 450 is less than the maximum width QD of the impactor Q is not limited to the X direction and can be any direction.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

What is claimed is:

1. A display device, comprising:
a display including a display surface; and
a holder that is provided on a surface of a side opposite the display surface of the display, and that fixes the display to a fixing target, wherein
in a state in which the display device is fixed to the fixing target, when an impactor impacts the display surface on a center line that passes through a center of a display region of the display and that is perpendicular to the display region, a rigidity to impact of the display device is asymmetrical.

2. The display device according to claim 1, wherein
the holder includes an open section, and
when viewed from above, a position of the center of the display region is offset from a position of a center of an opening, on a side of the display, of the open section, and a minimum width in one direction of the open section is less than a maximum width in the one direction of the impactor.

3. The display device according to claim 1, wherein
the holder includes a recess on a surface opposing the display, and
when viewed from above, a position of the center of the display region is offset from a position of a center of an opening of the recess, and a minimum width in one direction of the recess is less than a maximum width in the one direction of the impactor.

4. The display device according to claim 1, wherein
the holder includes an open section, and
when viewed from above, the holder includes a first portion and a second portion that oppose each other with the open section therebetween and that are formed from materials having mutually different rigidities, and a minimum width in one direction of the open section is less than a maximum width in the one direction of the impactor.

5. The display device according to claim 1, further comprising:
a plurality of the holders, wherein
when viewed from above, the plurality of holders is disposed asymmetrical to the center line that passes through the center of the display region and that is perpendicular to the display region, and a distance from an end of each of the holders to the center of the display region is less than half a maximum width of the impactor.

6. The display device according to claim 1, further comprising:
a plurality of the holders, wherein
an area of a surface, holding the display, of at least one of the holders differs from an area of a surface, holding the display, of the other holders, and
when viewed from above, a distance from an end of each of the holders to the center of the display region is less than half a maximum width of the impactor.

7. The display device according to claim 1, further comprising:
a plurality of the holders that fixes the display to the fixing target positioned on a side, opposite the display surface, of the display, wherein
when viewed from above, a position of the center of the display region is offset from a position of a center of a polygon surrounded by line segments that connect centers of the holders, and a shortest distance from the position of the center of the display region to an outer circumferential surface of each of the holders is less than half a maximum width of the impactor.

8. The display device according to claim 1, wherein
the display includes a display panel, a housing that accommodates the display panel, and a cover that is provided on the housing via an adhesive member and that protects the display panel, and
when viewed from above, thicknesses of portions of the adhesive member that oppose each other with the display panel therebetween differ.

9. The display device according to claim 1, wherein
the fixing target is supported, via the holder, from a side opposite a direction in which the impactor impacts the display, and
a rigidity of the fixing target is greater than the rigidity of the holder.
